(19) United States
(12) Patent Application Publication
(10) Pub. No.: US 2022/0073405 A1
(43) Pub. Date: Mar. 10, 2022

(54) HEATING APPARATUS AND METHOD FOR MANUFACTURING OPTICAL FIBER BASE MATERIAL

(71) Applicant: FURUKAWA ELECTRIC CO., LTD., Tokyo (JP)

(72) Inventors: Tsuneo SUZUKI, Tokyo (JP); Hiroshi MIYAKE, Tokyo (JP)

(73) Assignee: FURUKAWA ELECTRIC CO., LTD., Tokyo (JP)

(21) Appl. No.: 17/455,802

(22) Filed: Nov. 19, 2021

Related U.S. Application Data
(63) Continuation of application No. PCT/JP2020/021921, filed on Jun. 3, 2020.

(30) Foreign Application Priority Data
Jun. 6, 2019 (JP) 2019-106565

(51) Int. Cl. C03B 37/014; C03B 37/07

(52) U.S. Cl. CPC C03B 37/0146; C03B 37/07

(57) ABSTRACT

A heating apparatus includes: a furnace core tube configured to house a glass base material; a heating device installed at outer periphery of the furnace core tube; and a controller configured to control the heating device. The heating device includes a plurality of independently-controllable heaters arranged along a longitudinal direction of the glass base material. The heaters are grouped into a plurality of heating groups controllable in an independent manner by the controller. Each of the heating groups includes at least one of the heaters configured to heat the furnace core tube.

This application is a continuation of International Application No. PCT/JP2020/021921, filed on Jun. 3, 2020 which claims the benefit of priority of the prior Japanese Patent Application No. 2019-106565, filed on Jun. 6, 2019, the entire contents of which are incorporated herein by reference.

### BACKGROUND

The present disclosure is related to a heating apparatus for manufacturing a glass base material, and is related to a method for manufacturing an optical fiber base material.

In Japanese Patent Application Laid-open No. 2004-224655, as a configuration in which an optical fiber base material having excellent optical property is obtained as a result of precisely controlling the temperature gradient inside an electrical furnace, and in which a compact configuration may be achieved because of the fact that only a small number of power-supply devices are sufficient even when heaters are installed in multiple layers inside the electrical furnace; a configuration is disclosed which includes heating groups each having of a plurality of heaters, which includes a plurality of power supply units installed corresponding to the plurality of heating groups, and in which each power supply unit is connected in a switchable manner to one of the heaters in a heating group. According to the configuration disclosed in Japanese Patent Application Laid-open No. 2004-224655, even if the base material of an optical fiber becomes large in size, uniform heating of the base material may be performed at low cost. In Japanese Patent Application Laid-open No. H3-223133, a configuration is disclosed in which heaters made of molybdenum disilicide (MoSi₂) are installed in multiple layers. The heaters disclosed in Japanese Patent Application Laid-open No. H3-223133 are arranged in such a way that there is uniform heat distribution in the longitudinal direction of the optical fiber base material.

### SUMMARY

In a heating apparatus used in the dehydration process, accompanying an increase in the size of the optical fiber base material that is a glass base material, especially the furnace core tube has been becoming larger in size and more expensive. In order to ensure that the manufacturing cost does not increase, it is necessary to hold down any deterioration of the furnace core tube attributed to the disconnection of the heaters, to reduce the frequency of maintenance such as replacement, and to shorten the non-operational time of the heating apparatus.

Generally, as the heaters used in the dehydration process during the manufacturing of an optical fiber, there are heaters such as carbon heaters in which the radiant heat of carbon is used or heaters in which the radiant heat of molybdenum disilicide (MoSi₂) is used. Regarding the carbon heaters, integral molding needs to be performed in the circumferential direction of the furnace core tube. Hence, due to an increase in the size of the optical fiber base material, the diameter of the furnace core tube also increases and the carbon heaters that are fit at the outer periphery of the furnace core tube become more expensive. On the other hand, the heaters using molybdenum disilicide may be placed in a segmented manner in the circumferential direction. Hence, even if the diameter of the furnace core tube becomes large due to an increase in size of the optical fiber base material, that issue may be handled by increasing the number of heaters, and hence it does not cause a significant increase in the cost. However, as compared to carbon heaters, the heaters using molybdenum disilicide deteriorate at a faster rate and have lesser reliability. For that reason, it is a matter of concern that, as compared to carbon heaters, the heaters using molybdenum disilicide may get disconnected during the heating performed in the dehydration process.

There is a need for a heating apparatus and a method for manufacturing an optical fiber base material that are able to reduce the manufacturing cost of the optical fiber base material.

According to one aspect of the present disclosure, there is provided a heating apparatus including: a furnace core tube configured to house a glass base material; a heating device installed at outer periphery of the furnace core tube; and a controller configured to control the heating device, wherein the heating device includes a plurality of independently-controllable heaters arranged along a longitudinal direction of the glass base material, the heaters are grouped into a plurality of heating groups controllable in an independent manner by the controller, and each of the heating groups includes at least one of the heaters configured to heat the furnace core tube.

### BRIEF DESCRIPTION OF THE DRAWINGS

FIG. 1 is a side view illustrating a heating furnace according to an embodiment;

FIG. 2 is a cross-sectional view along II-II line illustrated in FIG. 1;

FIG. 3 is a graph illustrating an example of the temperature of the heating furnace and the temporal changes in a dehydration gas that is supplied according to the embodiment;

FIG. 4 is a flowchart for explaining a method for controlling a heater according to the embodiment;

FIG. 5 is a diagram corresponding to FIG. 2 and illustrating an example of the state in which a heating unit of the heater gets disconnected according to the embodiment; and

FIG. 6 is a cross-sectional view corresponding to FIG. 2 and illustrating a heating apparatus according to a modification example of the embodiment.

### DETAILED DESCRIPTION

An exemplary embodiment is described below with reference to the accompanying drawings. In the whole picture of the embodiment described below, identical or corresponding portions are referred to by the same reference numerals. Moreover, the present disclosure is not limited by the embodiment described below.

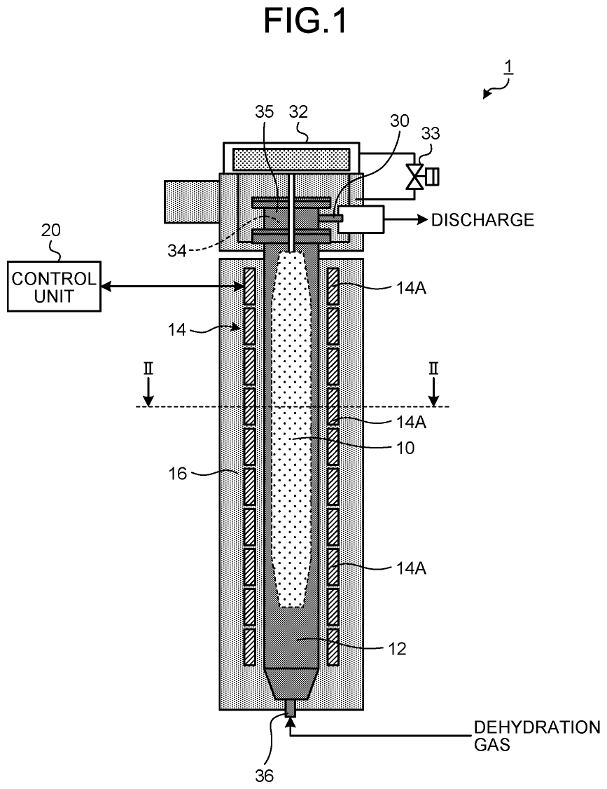

Firstly, given below is the explanation of a heating apparatus according to the embodiment. In FIG. 1 is illustrated the heating apparatus according to the embodiment. As illustrated in FIG. 1, a heating furnace 1 representing the heating apparatus according to the embodiment is meant for performing dehydration or vitrification of a glass base material 10 such as an optical fiber base material. The heating furnace 1 includes a furnace core tube 12, a multi-layer heater 14, a furnace body 16, and a control unit 20.

The furnace core tube 12 is a tube that is capable of housing the glass base material 10 and that extends in the vertical direction corresponding to the shape of the glass base material 10, that is, extends in the longitudinal direction of the glass base material 10. The furnace core tube 12 is made of, for example, silica glass. In the multi-layer heater 14 representing a heating device, a plurality of heaters 14A is laminated in the vertical direction at the outer periphery of the furnace core tube 12. In the example illustrated in FIG. 1, the multi-layer heater 14 is configured by laminating 10 heaters 14A. The multi-layer heater 14 is capable of heating the furnace core tube 12 under the control of the control unit 20. In the multi-layer heater 14, the heaters 14A are configured using, for example, molybdenum disilicide (MoSi₂). The furnace body 16 houses the furnace core tube 12 and the multi-layer heater 14. The furnace body 16 is made of a metal such as stainless steel. Meanwhile, in the furnace body 16, a coolant water system or a mold temperature controller may be further included at the outer periphery side of the multi-layer heater 14.

The upper end of the furnace core tube 12 is covered by a simple hood 32. In the upper part of the furnace core tube 12, a slot 34 is formed for enabling insertion and removal of the glass base material, and an upper lid 35 is placed for opening and closing the slot 34. In the upper lid 35, an exhaust pipe 30 is disposed through which gases from the inside of the furnace core tube 12 are emitted (discharged). In between the simple hood 32 and the exhaust pipe 30, a gate valve 33 is disposed. At the lower end of the furnace core tube 12, an inlet 36 is formed through which a gas is introduced (let) into the furnace core tube 12.

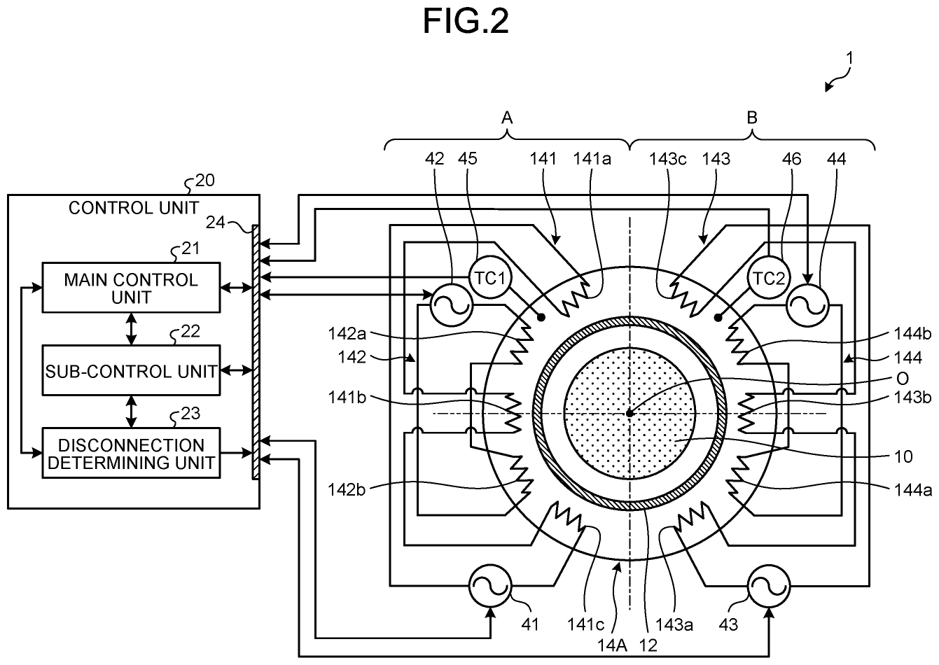

FIG. 2 is a cross-sectional view along II-II line illustrated in FIG. 1. As illustrated in FIG. 2, according to the present embodiment, each heater 14A that constitutes the multi-layer heater 14 in the heating furnace 1 is configured with a plurality of heating units, such as 10 heating units 141a, 142a, 141b, 142b, 141c, 143a, 144a, 143b, 144b, and 143c arranged in a concyclic manner along the outer periphery of the furnace core tube 12. That is, the heating units 141a to 143c are arranged in a substantially equidistant manner from their centers. Meanwhile, it is desirable that each heater 14A includes at least 10 heating units. Moreover, in the present embodiment, the heating units 141a to 144b are, for example, coil-shaped members made of a material including, for example, molybdenum disilicide (MoSi₂). In order to secure the durability of the heater 14A, the heater diameter (thickness) of the heating units 141a to 144b is typically 10 mm or more and is desirably 12 mm or more. In the present embodiment, the heater diameter is equal to, for example, 14 mm.

In the heater 14A illustrated in FIG. 2, the heating units are spatially divided into two regions, namely, regions A and B. The heating units 141a, 142a, 141b, 142b, and 141c are arranged in the region A. The heating units 143a, 144a, 143b, 144b, and 143c are arranged in the region B. The heating units 141a to 142b arranged in the region A and the heating units 143a to 144b arranged in the region B have plane symmetry with respect to the boundary plane between the regions A and B (i.e., with respect to a dashed-dotted line illustrated in FIG. 2) and have rotation symmetry with respect to a central axis O around which the glass base material 10 rotates. As a result, the temperature distribution in the regions A and B due to the heating by the heater 14A may be maintained to be symmetric between the regions A and B.

In the region A of the heater 14A, three heating units 141a to 141c are series-connected to constitute a heating group 141, and are able to receive the supply of electrical power from a power source 41. Similarly, two heating units 142a and 142b are series-connected to constitute a heating group 142, and are able to receive the supply of electrical power from a power source 42. In other words, a heating group typically includes at least one heating unit and typically includes a plurality of heating units; and the amount of heat generation by the heating units 141a to 141c constituting the heating group 141 may be controlled by the power source 41, and the amount of heat generation by the heating units 142a and 142b constituting the heating group 142 may be controlled by the power source 42. The power sources 41 and 42 are power supplies controllable in a mutually independent manner. It is desirable that the power sources 41 and 42 are independently installed for each of the heaters 14A arranged in multiple layers. The group of the heating units 141a to 141c and the group of the heating units 142a and 142b are arranged to have plane symmetry with respect to the plane that is orthogonal to the boundary plane of the regions A and B (i.e., with respect to a dashed-two dotted line illustrated in FIG. 2) (hereinafter, an orthogonal plane). Moreover, the group of the heating units 141a to 141c, which is controlled for heat generation by the power source 41, and the group of the heating units 142a and 142b, which is controlled for heat generation by the power source 42, are alternately arranged along the outer periphery of the furnace core tube 12. As a result, even if either one of the heating groups 141 and 142 malfunctions and is not able to generate heat due to disconnection, the furnace core tube 12 may still be heated in a symmetric manner with respect to the orthogonal plane using the other heating group. Thus, the heating may be performed in a balanced manner, with the other heating group ensuring that the temperature distribution at the outer periphery of the furnace core tube 12 is symmetrical.

In the region B of the heater 14A, the three heating units 143a to 143c are series-connected to constitute a heating group 143, and are able to receive the supply of electrical power from a power source 43. Similarly, the two heating units 144a and 144b are series-connected to constitute a heating group 144, and are able to receive the supply of electrical power from a power source 44. In other words, the amount of heat generation by the heating units 143a to 143c constituting the heating group 143 may be controlled by the power source 43, and the amount of heat generation by the heating units 144a and 144b constituting the heating group 144 may be controlled by the power source 44. The power sources 43 and 44 are power supplies controllable in a mutually independent manner. It is desirable that the power sources 43 and 44 are independently installed for each of the heaters 14A arranged in multiple layers. The group of the heating units 143a to 143c and the group of the heating units 144a and 144b are arranged to have plane symmetry with respect to the orthogonal plane. Moreover, the group of the heating units 143a to 143c, which is controlled for heat generation by the power source 43, and the group of the heating units 144a and 144b, which is controlled for heat generation by the power source 44, are alternately arranged along the outer periphery of the furnace core tube 12. As a result, even if either one of the heating groups 143 and 144 malfunctions and is not able to generate heat, the furnace core tube 12 may still be heated in a symmetric manner with respect to the orthogonal plane using the other heating group. Thus, the heating may be performed in a balanced manner, with the other heating group ensuring that the temperature distribution at the outer periphery of the furnace core tube 12 is symmetrical.

Meanwhile, in the present embodiment, although the heating units constituting heating groups are divided into two regions A and B, they may also be divided into three or more regions. More particularly, when the heating units are divided into an odd number of regions equal to or greater than three regions, it is desirable that each heating unit is arranged to have rotation symmetry for an odd number of times with respect to the central axis O around which the glass base material 10 rotates. When the heating units are divided into an even number of regions equal to or greater than four regions, in an identical manner to the case in which the heating units are divided into the two regions A and B, it is desirable that each heating unit is arranged to have plane symmetry with respect to the boundary plane of two regions and to have rotation symmetry for an even number of times with respect to the central axis O. Moreover, it is desirable that a temperature sensor is installed in each of a plurality of regions. However, there is no restriction on the installation positions of the temperature sensors. Moreover, also in the case in which the heating units are divided into three or more regions, it is desirable that a single temperature sensor is installed in each region. However, there is no restriction on the installation positions of the temperature sensors.

Meanwhile, the heating units constituting the heating groups may be arranged without dividing them into regions. That is, a plurality of heating groups may be arranged in a single region. For example, when two heating groups are arranged at the outer periphery of the furnace core tube 12, a plurality of heating units constituting one of the heating groups is connected to each other and is supplied with electrical power from one power source, and a plurality of heating units constituting the other heating group is connected to each other and is supplied with electrical power from another power source. Besides, it is desirable that a plurality of heating units constituting one heating group and a plurality of heating units constituting the other heating group are alternately arranged along the outer periphery of the furnace core tube 12. With that, it becomes possible to achieve the same effect as the effect explained above. Moreover, a plurality of heating units constituting one heating group and a plurality of heating units constituting the other heating group may be arranged to have plane symmetry with respect to the plane passing through the central axis O. Even when three or more heating groups are placed, it is desirable that a plurality of heating units constituting each heating group is arranged in such a way that there is no variability in the temperature distribution along the outer periphery of the furnace core tube 12.

As a result of having such a layered configuration of a plurality of heaters 14A and as a result of controlling each heater 14A using the control unit 20, the heating performed by the multi-layer heater 14 gets controlled. The control unit 20 includes a main control unit 21, a sub-control unit 22, a disconnection determining unit 23, and a signal selector 24. Among the main control unit 21, the sub-control unit 22, and the disconnection determining unit 23; information may be input and output using signals. The signal selector 24 performs signal input switching in which the signals supplied to the control unit 20 from outside are input either to the main control unit 21 or to the sub-control unit 22; as well as selectively outputs the signals, which are output from the main control unit 21 or the sub-control unit 22, to a predetermined destination.

More particularly, the control unit 20 includes a processor (not illustrated) such as a central processing unit (CPU), a digital signal processor (DSP), or a field-programmable gate array (FPGA); and includes a main memory unit (not illustrated) such as a random access memory (RAM) or a read only memory (ROM). Moreover, the control unit 20 includes a memory unit (not illustrated). The memory unit is configured using a memory medium selected from among an erasable programmable ROM (EPROM), a hard disk drive (HDD), and a removable media. Examples of the removable media include a universal serial bus (USB) memory, and a disc recording medium such as a compact disc (CD), a digital versatile disc (DVD), or a Blu-ray (registered trademark) disc. The memory unit may be used to store an operating system (OS), various computer programs, various tables, and various databases. The control unit 20 loads the computer programs from the memory unit into the work area of the main memory unit and executes them. As a result of executing the computer programs, the control unit 20 controls the constituent elements and implements the functions intended for achieving a predetermined objective. In the present embodiment, the control unit 20 may implement the functions of the main control unit 21, the sub-control unit 22, the disconnection determining unit 23, and the signal selector 24.

In the regions A and B of the heater 14A, temperature sensors 45 and 46 are respectively installed as temperature measuring units. The temperature sensors 45 and 46 are used to measure the temperature of the outer periphery portion of the furnace core tube 12. The measured values of the temperature are supplied to the control unit 20. Then, the signal selector 24 supplies the measured values of the temperature, which have been supplied to the control unit 20, to the main control unit 21 or the sub-control unit 22. Based on the measured values of the temperature, the control unit independently controls the power sources 41 to 44 representing the power source units of the heater 14A. That is, the control unit 20 independently controls the power sources 41 to 44 in such a way that the measured values of the temperature, which are measured by the temperature sensors 45 and 46, are set to an appropriate temperature.

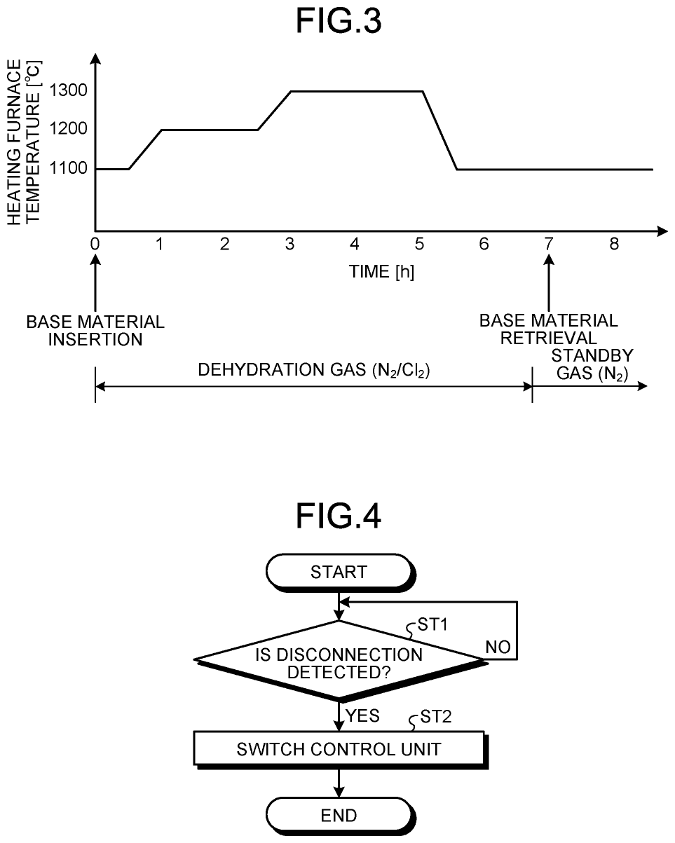

Given below is the explanation of the operation of heating the glass base material 10 in the heating furnace 1. FIG. 3 is a graph illustrating an example of the temperature of the heating furnace 1 and the temporal changes in the dehydration gas that is supplied. As illustrated in FIG. 3, firstly, the main control unit 21 of the control unit 20 controls the power sources 41 to 44, so that electrical power is supplied from the power sources 41 to 44 to the heaters 14A configured in multiple layers. As a result, heating gets started. In the standby state in which the glass base material 10 is not yet inserted in the heating furnace 1, the heating temperature is adjusted approximately in the range of 1000° C. to 1100° C. for the protection of the furnace core tube 12. Subsequently, the glass base material 10 representing a fiber base material is inserted inside the furnace core tube 12. Moreover, a dehydration gas is supplied inside the furnace core tube 12 from outside through the inlet 36 formed at the bottom portion. The dehydration gas is a mixed gas made of, for example, a halogen gas such as chlorine (Cl₂) and an inert gas such as nitrogen (N₂) or helium (He). Inside the furnace core tube 12, the gas rises upward and flows out from the exhaust pipe 30 present in the upper portion. After the glass base material 10 is inserted in the furnace core tube 12 of the heating furnace 1, the electrical power supplied to the multi-layer heater 14 is increased so as to adjust the heating temperature inside the furnace core tube 12 approximately in the range of 1200° C. to 1300° C. As a result, dehydration of the glass base material 10 is carried out.

Given below is the explanation of the method for controlling the heater 14A. FIG. 4 is a flowchart for explaining the method for controlling the heater 14A according to the present embodiment. As illustrated in FIG. 4, at Step ST1, during the period of time in which the main control unit 21 of the control unit 20 is controlling the power sources 41 to 44, the disconnection determining unit 23 detects disconnection or no disconnection based on the output of the power sources 41 to 44. While the heating is being performed by the heater 14A, based on the voltage values supplied from the power sources 41 to 44, the disconnection determining unit 23 determines whether or not any of the heating units 141a to 144b is disconnected. If it is determined that none of the heating units 141a to 144b is disconnected (No at Step ST1), then the disconnection determining unit 23 again performs the operation at Step ST1.

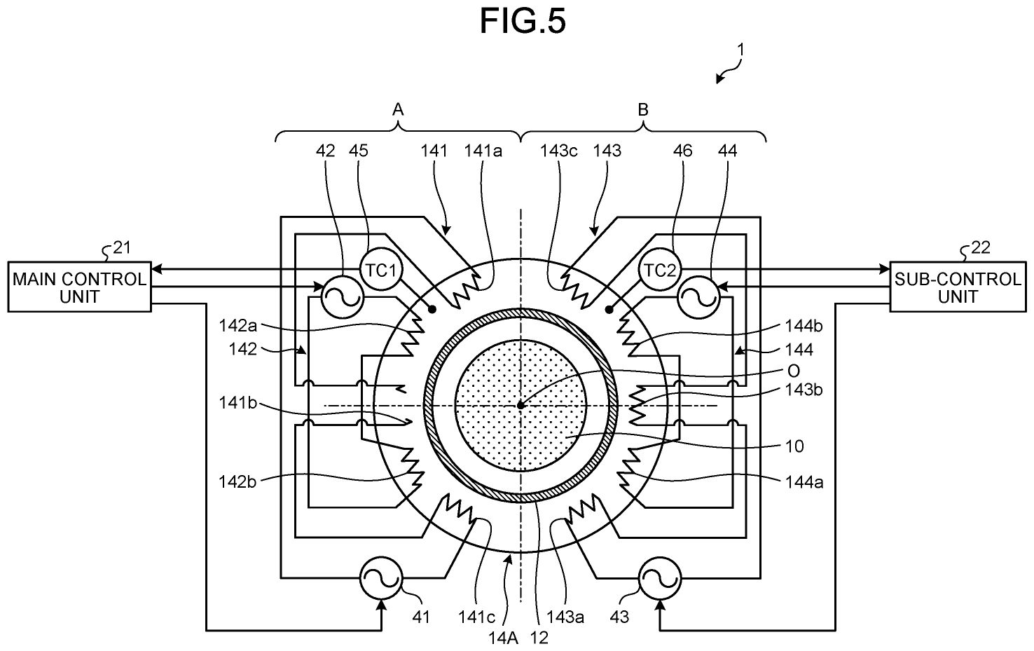

On the other hand, if the disconnection determining unit 23 determines that any of the heating units 141a to 144b is disconnected (Yes at Step ST1), then the system control proceeds to Step ST2. FIG. 5 is a diagram illustrating an example of the state in which a heating unit of the heater 14A gets disconnected. In the example illustrated in FIG. 5, the heating unit 141b of the heating group 141 in the region A has got disconnected. Thus, at Step ST2, the disconnection determining unit 23 switches the signal selector 24, so as to switch the control of the power sources 43 and 44 in the region B, which is the region having no disconnection, from the main control unit 21 to the sub-control unit 22. On the other hand, in the region A that is the region having disconnection, the disconnection determining unit 23 retains the control of the main control unit 21 with respect to the power source 42 that supplies electrical power to the heating group 142 having no disconnection. As a result, in the heater 14A, based on the measured value of temperature as obtained by the temperature sensor 45, the main control unit 21 controls a single power source 41 and two heating units 142a and 142b, and adjusts the temperature distribution in the area A. Herein, the main control unit 21 controls the power source 41 in such a way that the temperature distribution in the outer periphery portion of the furnace core tube 12 approaches the temperature distribution identical to the case in which the heating is performed using the heating groups 141 and 142. On the other hand, in the heater 14A, based on the measured value of temperature as obtained by the temperature sensor 46, the sub-control unit 22 controls two power sources 43 and 44 and five heating units 143a to 144b, and adjusts the temperature distribution in the region B. This is the way in which the control operation is performed with respect to the heater 14A.

In the method for manufacturing an optical fiber base material using the heating furnace 1, firstly, a known method such as the VAD method is implemented to form the core and to form a porous glass on the outer periphery of the core. With that, a porous optical fiber base material (the glass base material 10) is manufactured. Then, the porous optical fiber base material is inserted in the furnace core tube 12 of the heating furnace 1, and thermal dehydration is performed in an atmosphere that includes at least a dehydration gas. Subsequently, the porous glass is sintered to obtain a transparent glass. With that, a glass base material representing the optical fiber base material is manufactured.

As explained above, according to the embodiment, for example, of the two heating groups 141 and 142 having series-connected heating units in the region A, even if the heating group 141 becomes unable to generate heat due to the disconnection of the heating unit 141b, the furnace core tube 12 may be continually heated using the other heating group 142. Hence, the poor heating performed by the heating group 141 may be compensated by the heating performed by the heating group 142, thereby enabling reduction in the likelihood of termination of the dehydration of the glass base material 10. That is, in the multi-layer heater 14 configured in multiple layers, even if there is some kind of trouble such as disconnection in any heater 14A thereby causing incapability in heat generation for the heating group 141; it is still possible to enhance the likelihood of being able to finish the dehydration of the glass base material 10 without causing any trouble such as devitrification of the furnace core tube 12.

### Modification Example

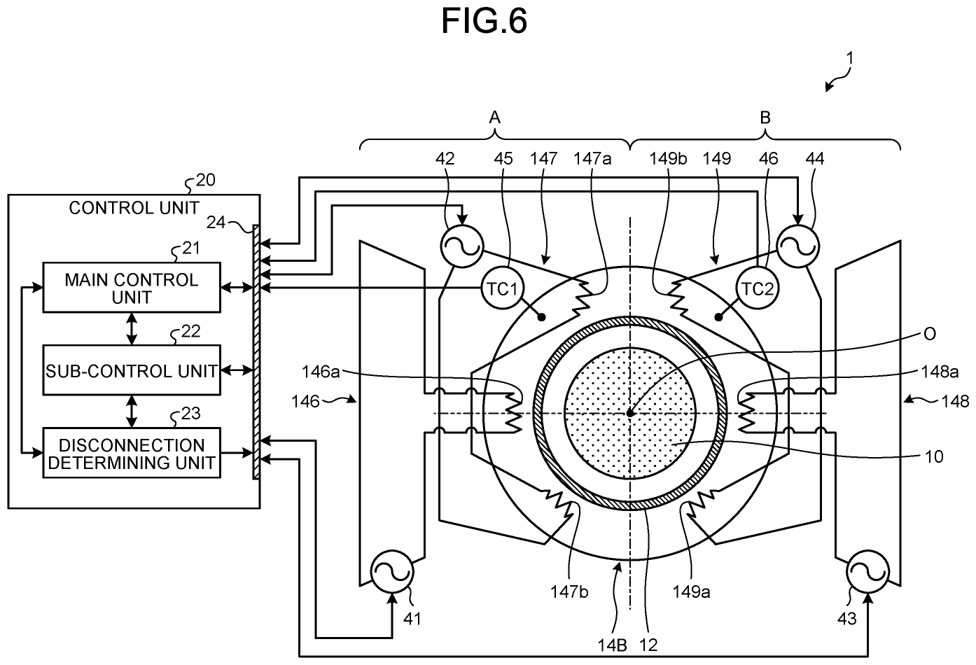

Given below is the explanation of a modification example of the embodiment. FIG. 6 is a cross-sectional view, along II-II line illustrated in FIG. 1, of a heating apparatus according to the modification example. As illustrated in FIG. 6, each heater 14B that constitutes the multi-layer heater 14 in the heating furnace 1 is configured with six heating units 147a, 146a, 147b, 149a, 148a, and 149b according to the modification example that are arranged in a concyclic manner along the outer periphery of the furnace core tube 12. That is, the heating units 146a to 149b are arranged in a substantially equidistant manner from their centers. Meanwhile, it is desirable that each heater 14B includes at least six heating units. Moreover, in the present modification example, the heating units 146a to 149b are, for example, coil-shaped members made of a material including, for example, molybdenum disilicide (MoSi₂). In order to secure the durability of the heater 14B, the heater diameter (thickness) of the heating units 146a to 149b is typically 10 mm or more and is desirably 12 mm or more. In the present modification example, the heater diameter is equal to, for example, 14 mm.

In the heater 14B illustrated in FIG. 6, the heating units are spatially divided into two regions, namely, the regions A and B. The heating units 147a, 146a, and 147b are arranged in the region A. The heating units 149a, 148a, and 149b are arranged in the region B. The heating units 147a, 146a, and 147b arranged in the region A and the heating units 149a, 148a, and 149b arranged in the region B have plane symmetry with respect to the boundary plane between the regions A and B (i.e., with respect to a dashed-dotted line illustrated in FIG. 6) and have rotation symmetry with respect to the central axis O around which the glass base material 10 rotates. As a result, the temperature distribution generated in the regions A and B due to the heating of the heater 14B may be maintained to be symmetric between the regions A and B. As a result, the temperature distribution generated in the regions A and B due to the heating by the heater 14B may be maintained to be symmetric between the regions A and B.

In the region A of the heater 14B, a single heating unit 146a constitutes a heating group 146, and is able to receive the supply of electrical power from the power source 41. Similarly, two heating units 147a and 147b are series-connected to constitute a heating group 147, and are able to receive the supply of electrical power from the power source 42. In other words, a heating group typically includes at least one heating unit; and the amount of heat generation by the heating unit 146a constituting the heating group 146 may be controlled by the power source 41, and the amount of heat generation by the heating units 147a and 147b constituting the heating group 147 may be controlled by the power source 42. The power sources 41 and 42 are power supplies controllable in a mutually independent manner. It is desirable that the power sources 41 and 42 are independently installed for each of the heaters 14B arranged in multiple layers. The heating unit 146a and the group of the heating units 147a and 147b are arranged to have plane symmetry with respect to the plane that is orthogonal to the boundary plane of the regions A and B (i.e., with respect to a dashed-two dotted line illustrated in FIG. 6) (hereinafter, an orthogonal plane). Moreover, the heating unit 146a, which is controlled for heat generation by the power source 41, and the group of the heating units 147a and 147b, which is controlled for heat generation by the power source 42, are alternately arranged along the outer periphery of the furnace core tube 12. As a result, even if either one of the heating groups 146 and 147 malfunctions and is not able to generate heat due to disconnection, the furnace core tube 12 may still be heated in a symmetric manner with respect to the orthogonal plane using the other heating group. Thus, the heating may be performed in a balanced manner, with the other heating group ensuring that the temperature distribution at the outer periphery of the furnace core tube 12 is symmetrical.

In the region B of the heater 14B, a single heating unit 148a constitutes a heating group 148, and is able to receive the supply of electrical power from the power source 43. Similarly, the two heating units 149a and 149b are series-connected to constitute a heating group 149, and are able to receive the supply of electrical power from the power source 44. In other words, the amount of heat generation by the heating unit 148a constituting the heating group 148 may be controlled by the power source 43, and the amount of heat generation by the heating units 149a and 149b constituting the heating group 149 may be controlled by the power source 44. The power sources 43 and 44 are power supplies controllable in a mutually independent manner. It is desirable that the power sources 43 and 44 are independently installed for each of the heaters 14B arranged in multiple layers. The heating unit 148a and the group of the heating units 149a and 149b are arranged to have plane symmetry with respect to the orthogonal plane. Moreover, the heating unit 148a, which is controlled for heat generation by the power source 43, and the group of the heating units 149a and 149b, which is controlled for heat generation by the power source 44, are alternately arranged along the outer periphery of the furnace core tube 12. As a result, even if either one of the heating groups 148 and 149 malfunctions and is not able to generate heat, the furnace core tube 12 may still be heated in a symmetric manner with respect to the orthogonal plane using the other heating group. Thus, the heating may be performed in a balanced manner, with the other heating group ensuring that the temperature distribution at the outer periphery of the furnace core tube 12 is symmetrical.

As explained above, also in the modification example of the embodiment, it is possible to achieve the same effect as achieved in the embodiment.

Herein, although the description is given about the embodiment, the technical scope is not limited to the embodiment described above, and may be construed as embodying various deletions, alternative constructions, and modifications that may occur to one skilled in the art that fairly fall within the basic teaching herein set forth. For example, the numerical values mentioned in the embodiment are only exemplary, and different numerical values may be used as may be necessary.

For example, in the embodiment described above, when disconnection occurs, the control of the heating groups 143 and 144 in the region B having no disconnection is switched from the main control unit 21 to the sub-control unit 22. Alternatively, the control of the heating groups 141 and 142 in the region A having disconnection may be switched from the main control unit 21 to the sub-control unit 22. Meanwhile, the main control unit 21 and the sub-control unit 22 may be configured either using a physically single processor or using different processors.

The present disclosure is useful in the manufacturing of an optical fiber base material.

The heating apparatus and the method for manufacturing an optical fiber base material according to the present disclosure enable achieving reduction in the manufacturing cost of the optical fiber base material.

Although the disclosure has been described with respect to the specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A heating apparatus comprising:
a furnace core tube configured to house a glass base material;
a heating device installed at outer periphery of the furnace core tube; and
a controller configured to control the heating device, wherein
the heating device includes a plurality of independently-controllable heaters arranged along a longitudinal direction of the glass base material,
the heaters are grouped into a plurality of heating groups controllable in an independent manner by the controller, and
each of the heating groups includes at least one heating unit configured to heat the furnace core tube.

2. The heating apparatus according to claim 1, wherein
each of the heating groups includes a power source configured to supply electrical power to that heating group, and
the controller is configured to independently control the power source included in each of the heating groups.

3. The heating apparatus according to claim 2, further comprising temperature measuring circuitry configured to measure temperature of the furnace core tube, wherein
based on measured value as obtained by the temperature measuring circuitry, the controller is configured to adjust electrical power supplied to each of the heating groups.

4. The heating apparatus according to claim 1, wherein the heating group includes a plurality of the heating units.

5. The heating apparatus according to claim 1, wherein the heater includes at least six of the heating units.

6. The heating apparatus according to claim 1, wherein the at least one heating unit is configured using molybdenum disilicide.

7. The heating apparatus according to claim 1, wherein heater diameter of the at least one heating unit is equal to or greater than 10 mm.

8. A method for manufacturing an optical fiber base material, the method being executed by using a heating apparatus including: a furnace core tube configured to house a porous optical fiber base material made of a core and a porous glass formed at outer periphery of the core, a heating device installed at outer periphery of the furnace core tube, and a controller configured to control the heating device, wherein the heating device includes a plurality of independently-controllable heaters arranged along a longitudinal direction of the porous optical fiber base material, the heaters are grouped into a plurality of heating groups controllable in an independent manner by the controller, and each of the heating groups includes at least one heating unit configured to heat the furnace core tube, the method comprising:
inserting the porous optical fiber base material in the furnace core tube of the heating apparatus; and
performing thermal dehydration in an atmosphere that includes at least a dehydration gas.
